(19) United States
(12) Patent Application Publication
(10) Pub. No.: US 2026/0358114 A1
(43) Pub. Date: Nov. 12, 2026

(54) BACKLIGHT VISION SYSTEM FOR A POSITION-DETERMINING SYSTEM AND/OR A POSITION-CORRECTING SYSTEM

(71) Applicant: CELLCENTRIC GMBH & CO. KG, Kirchheim/Teck-Nabern (DE)

(72) Inventors: Thomas MAASSEN, Burnaby (CA); Zlatko HADZIAVDIC, Burnaby (CA); Taryn BIGGS, Burnaby (CA); Gurdip KHAIRA, Burnaby (CA); Arkadi IVANNIKOV, Burnaby (CA)

(21) Appl. No.: 19/484,420

(22) PCT Filed: May 17, 2024
(86) PCT No.: PCT/EP2024/063671

§ 371 Date: Nov. 14, 2025

(30) Foreign Application Priority Data
May 17, 2023 (DE) 102023204678.4

(51) Int. Cl. G01B 11/00

(52) U.S. Cl. CPC G01B 11/002; B65G 2203/041

(57) ABSTRACT

The invention relates to a system (1) for determining and/or correcting the position of an object (10), said system comprising: at least one reference marking (2) which is designed to indicate a desired position of an object (10); an object support device (3) for holding the object (10); a backlighting device (5) for backlighting the at least one reference marking (2) and for backlighting at least one part of the object (10); at least one capturing device (6) for capturing an image, the capturing device (6) being designed to detect an actual position of the object (10), in particular based on the at least one positional feature of the object (10), and the desired position of the object (10), in particular based on the at least one reference marking (2); and at least one position-correcting device (9) which is designed to correct the position of the captured object (10) based on the detected actual position and the detected desired position of the object (10).

The present invention relates to a system for determining or detecting the position and/or correcting the position of an object and to a method for correcting the position.

It is usually difficult to adjust the position of an object, in particular for further processing in a process, in particular so that a subsequent manufacturing step can be carried out with precise tolerances. If these tolerances cannot be maintained in the process or are difficult to maintain, rejects are created which, among other things, waste (expensive) material, in particular, a function can be restricted due to inaccurate position adjustment.

It is an object of the invention, in particular, to improve determining a position or detecting a position and/or a position accuracy of an object.

This object is achieved according to the teaching of the independent claims. Various embodiments and refinements of the invention are the subject matter of the dependent claims.

According to one embodiment of the invention, a system for determining the position and/or correcting the position of an object is provided. In one embodiment, the position-determining and/or position-correcting system has at least one reference marking, which is in particular constructed to indicate a desired position of an object. In one embodiment, the position-determining and/or position-correcting system comprises an object carrier device. In one embodiment, the object carrier device is configured or used to receive an object, in particular an object the position of which is to be determined and/or corrected. In one embodiment, the position-determining and/or position-correcting system comprises a backlighting device which is configured or used to backlight at least a part of the object, in particular the object the position of which is to be determined and/or corrected, in particular to backlight at least one positional feature of the object. In one embodiment, the backlighting device is additionally or alternatively configured to backlight the at least one reference marking or the backlighting device is used for this purpose. In one embodiment, the position-determining and/or position-correcting system comprises at least one capturing device which is configured to receive at least a part of the object, in particular at least one positional feature of the object, alternatively or additionally, in one embodiment, to receive at least one reference marking. In one embodiment, the capturing device is configured to capture or detect an image, in particular a two-dimensional and/or three-dimensional image (in particular with depth information), wherein the image, in particular the detected image, or the perspective of the capturing device comprises at least a part of the object, in particular at least one positional feature of the object and/or the at least one reference marking.

In one embodiment, this advantageously makes it possible for an actual position of an object, the position of which is to be determined, to be determined (more) precisely, in particular for an object, the position of which is to be determined, to be or be able to be determined (more) precisely in its position with respect to a or the desired position, in particular for an actual position to be able to be determined or to be determined, which, in a particularly advantageous manner, improves or can improve a position tolerance in a subsequent process step.

In one embodiment, the system for determining and/or correcting the position comprises at least one position-correcting device which is configured to correct the position of the object received in the object carrier device, in particular based on the actual position, detected in particular by the capturing device, and the desired position, detected in particular by the capturing device, and further in particular from a position correction shift, in particular translation and/or rotation, determined from the desired position and the actual position, so that the object is or can be moved into the desired position, in particular so that the object is transferred into the desired position by the position-correcting device.

In one embodiment, this advantageously makes it possible for an actual position of an object, the position of which is to be corrected, to be corrected or to be correctable, in particular for an object to be brought into a desired position which, in a particularly advantageous manner, improves or can improve a position tolerance in a subsequent process step.

In one embodiment, the object carrier device and the at least one position-correcting device are operatively joined to one another, in particular integrally, further in particular in such a way that an object located on or in the object carrier device can be position-corrected with the aid of the object carrier device, in particular can be aligned or corrected according to a desired position, further in particular can be transferred into the desired position. In one embodiment, the object carrier device is arranged in a plane in which the object is or can be corrected in its position, in particular by the position-correcting device. In one embodiment, the plane corresponds to an xy-plane.

This advantageously makes it possible for the object to be influenced (more) easily in its position with respect to the desired position, in particular for its actual position to be changed. Advantageously, in one embodiment, a position-correcting device, which is (operatively) joined to the object carrier device, does not require its own contact point on the object, by means of which the object could be damaged during a position-correcting movement of the position-correcting device. Advantageously, the system described herein, in one embodiment, can enable an object to be positioned without being moved or bumped or otherwise positioned with a positional feature or edge against, for example, a reference pin or the like. In one embodiment, in the case of sensitive objects with or made of particularly brittle material(s), the object can be protected, in particular from damage, by manipulating the position of the object in such a way that at least one positional feature of the object or its edge(s) can be or are transferred into a desired position without collision.

In one embodiment, the device comprises a referencing device. In one embodiment, the backlighting device is arranged on the referencing device, in particular integrated in the referencing device, in particular detachably or non-detachably.

In one embodiment, this advantageously makes it possible to provide a simple or simpler, in particular integrated, referencing device with backlighting for in particular a reference marking and/or the object (to be position-corrected).

In one embodiment, the backlighting device is arranged on the object carrier device, in particular integrated therein, in particular (non-destructively) detachable or non-detachable.

In one embodiment, this advantageously makes it possible to provide a simple or simpler, in particular integrated, object carrier device with backlighting for in particular a reference marking and/or the object (to be position-corrected).

In one embodiment, the reference marking is arranged at a distance from the backlighting device, in particular at a distance in the z-direction (relative to the xy-plane of the object carrier device), or arranged on or at the backlighting device, in particular if, in one embodiment, the backlighting device, or in particular at least a part of the backlighting device, is arranged on the referencing device, in particular is integrally joined thereto, further in particular (non-destructively) detachable and/or non-detachable. In one embodiment, the reference marking is arranged at a distance from the backlighting device, in particular if, in an embodiment, the backlighting device, or in particular at least a part of the backlighting device, is arranged on the object carrier device, in particular is integrally joined thereto, further in particular (non-destructively) detachable and/or non-detachable. In one embodiment, the backlighting device has a translucent, in particular, at least substantially, transparent or semitransparent, surface onto which light is emitted from at least one lamp or at least one illuminant in such a way that a reference marking arranged on or at, in particular on the surface of the backlighting device and/or that a reference marking arranged at a distance from the backlighting device is or can be backlit.

Advantageously, if in one embodiment the reference marking is arranged at a distance from the backlighting device, it can be made possible in one embodiment that a small or smaller field of view for the capturing device can be or is implemented. In particular, if in one embodiment the reference marking is arranged on or at or above or at a distance from the backlighting device, the actual position can be determined (more) easily.

In one embodiment, the object carrier device and/or the backlighting device is configured to provide a negative pressure. In one embodiment, the provided negative pressure can advantageously be used to fix the object on the object carrier device and/or the backlighting device or these devices are constructed or configured for this purpose. In one embodiment, the object carrier device and/or the backlighting device has holes or the like by means of or through which the negative pressure can or does act on the object.

Advantageously, in one embodiment, this makes it possible for the object to remain in its position on the object carrier device, in particular not to slip or be able to slip, in the event of, for example, movements or vibrations of at least one of the components of the system.

In one embodiment, a light emitted by the backlighting device has a wavelength and/or a wavelength range that lies in the visible spectrum or wavelength range and/or a wavelength and/or a wavelength range that lies in the non-visible spectrum or wavelength range, in particular in the ultraviolet and/or infrared.

In one embodiment, this advantageously makes it possible for the capturing device to be able to be or to be specifically tuned to the emitted wavelength(s), and furthermore, in particular, for a user not to be or be able to be dazzled by the backlighting device. In one embodiment, this can (further) improve a contrast for the capturing device, in particular, in one embodiment, by means of filters, or by using fluorescence (effects).

In one embodiment, the backlighting device has a plurality of, in particular mutually independent, backlighting elements which, in one embodiment, are configured to backlight at least one and/or at most one reference marking, alternatively or additionally to backlight at least one and/or at most one positional feature of the object.

Advantageously, in one embodiment, this can provide targeted backlighting of reference marking(s) and/or positional features of the object.

In one embodiment, the capturing device has a plurality of cameras, in particular one camera for each reference marking, in particular one camera for each of at least two of the reference markings and/or for each positional feature of the object, in particular in such a way that the field of view or the perspective of the respective camera has at least one reference marking, at least two reference markings and/or one positional feature of the object.

In one embodiment, this advantageously allows the pose of the camera to be determined and advantageously an actual position and a desired position of the object.

In one embodiment, the capturing device has reference markings, in particular for determining a pose of the plurality of cameras. For this purpose, in one embodiment, the capturing device can have a higher-level camera which is configured to determine the pose of the plurality of cameras, in particular with respect to the at least one reference marking and thus in particular with respect to a desired position of the object.

In one embodiment, this advantageously makes it possible for a (self) position or (self) pose determined by a camera on the basis of the at least one reference marking or the at least two reference markings to be checked, in particular to be determined independently and/or redundantly.

In one embodiment, the position-correcting device is configured to correct a position of the object in a spatial plane, in particular in an xy-plane, in particular in a plane in which the object carrier device is arranged and/or the position-correcting device can change or correct a position or is configured to do so. In one embodiment, the object carrier device is aligned parallel to a floor or “is level” (horizontally).

In one embodiment, the referencing device is constructed for a carrier system process or a pick-and-place process. In one embodiment, the referencing device can be used as a carrier or for a carrier in a carrier system or is configured for this purpose; in particular, the referencing device itself and/or the receptacles of the referencing device are constructed to externally reference a desired position of the object.

Advantageously, in one embodiment, a further process step can thus be carried out on the object with precise location or position, in particular (more) precisely.

In one embodiment, the referencing device is constructed as a carrier structure. In one embodiment, the referencing device is constructed as a frame, in particular such that the object carrier device is arranged within the frame of the referencing device. In one embodiment, the at least one reference marking protrudes from the referencing device into the frame of the referencing device, in particular in such a way that a distance from the reference marking to the object is or becomes reduced, in particular in such a way that, in one embodiment, the field of view or the perspective of the capturing device is advantageously smaller, in particular compared to a capturing device the field of view of which captures the entire object and the at least one reference marking. Advantageously, in one embodiment, the capturing device can determine its position with respect to the referencing device and/or the reference marking if the at least one reference marking is constructed for this purpose, in particular for a three-dimensional position determination of the capturing device. In one embodiment, the perspective of the capturing device has at least two reference markings, so that a position or pose (position and orientation) of the capturing device can be or is determined with respect to the reference markings and thus in particular with respect to a desired position for the object.

In one embodiment, the referencing device, in particular the referencing device constructed as a frame, has at least two receptacles which are configured for fastening a (reference) centering device or are themselves constructed as a (reference) centering device, in particular for aligning a device receiving the referencing device, in particular a higher-level device, such as in particular a robot and/or a carrier system, to the desired position of the object. In one embodiment, the reference markings are joined to the referencing device in such a way that a position of the reference markings relative to the at least two receptacles, in particular the (reference) centering devices, is known, in particular with a predetermined tolerance.

In one embodiment, the at least two receptacles of the referencing device can be used to determine a desired position, in particular with the aid of a mask which is representative of the desired position and, in one embodiment, can be arranged in the at least two receptacles, in particular with repeatable accuracy, or is arranged in them to determine a desired position for the object. In one embodiment, a desired position of the object can then be determined or specified by means of the capturing device and the at least one reference marking.

Advantageously, this makes it possible to (more) quickly determine a desired position for different objects, in particular by using different masks for the respective object. In one embodiment, a desired position can advantageously be calibrated (more) quickly.

In one embodiment, the backlighting is provided with colored light, in particular with light of a wavelength or a wavelength range that can be assigned to a light color. In one embodiment, the backlighting is provided by means of light-emitting diode(s).

Advantageously, in one embodiment, a simple or simpler backlighting can be implemented, in particular a contrast of the at least one reference marking and the at least one positional feature of the object can be (further) increased.

In one embodiment, the reference marking comprises a chamfer. In one embodiment in which the reference marking is spaced apart from the backlighting device, the chamfer is formed in the direction of the backlighting device, in particular such that, in one embodiment, advantageously only one edge of the reference marking is visible to the capturing device, in particular the reference marking has only one edge as a reference for the capturing device.

Advantageously, in one embodiment, this makes it possible to improve the determination of the position of the object, in particular to make it (more) precise.

In one embodiment, the reference marking is arranged such that an edge of the reference marking, in particular a lower edge or an upper edge of the reference marking, further in particular an edge of the reference marking by means of which the position of the object is determined, is at a height with the (at least one) positional feature of the object, in particular at the same height of the object, provided that, in one embodiment, the object is an object which has an at least substantially planar surface, wherein the height in this embodiment relates or can relate to the thickness of the object and/or to a z-direction. In one embodiment, the height, in particular in the z-direction, of the object can be minimal relative to the extent, in particular in the alignment plane (x, y). In one embodiment, this can be particularly advantageous for, at least essentially, cuboid-shaped objects.

In one embodiment, the reference marking is constructed such that, based on the reference marking, a desired position of the object can be determined in at least two, in particular independent, (spatial) directions, in particular the x- and y-directions, in particular in three, further in particular independent, (spatial) directions, in particular the x-, y- and z-directions; in one embodiment, with the aid of the at least one capturing device.

In this way, in one embodiment, the number of reference markings can be advantageously reduced, in particular a number of capturing devices can be reduced, in particular because, in one embodiment, few(er) fields of view, in particular small(er) fields of view, are required to specify or determine a position or pose of the capturing device and/or a desired position, alternatively or additionally to determine an actual position of the object.

In one embodiment, the reference marking is arranged such that a distance between the reference marking and the object is reduced, in particular compared to reference marking(s) arranged on the referencing device. In one embodiment, the at least one reference marking is arranged between the referencing device and the desired position of the object, in particular in such a way that the at least one reference marking can be or is backlit by the backlighting device. In one embodiment, the at least one reference marking is arranged on and/or above the backlighting device, in particular at a distance in the z-direction, in such a way that the reference marking can be or is backlit.

In one embodiment, this makes it possible to increase the contrast for detecting the at least one reference marking and/or the at least one part of the object, in particular the at least one positional feature, in particular compared to a system without backlighting or without a backlighting device.

In one embodiment, the (at least one) positional feature is an edge of the object, in particular an edge of the object that corresponds to at least one determination and/or correction plane and/or determination and/or correction direction of the position-correcting device and/or an x- and y-direction. If, in one embodiment, the object is to be determined (only) in one plane and/or its position is to be corrected, in particular an edge of the object can be parallel to this plane. This edge can then, in one embodiment, be used as a positional feature, in particular the object can be position-corrected based on a correlation of this positional feature with respect to the at least one reference marking or with respect to a first reference marking and with respect to a second reference marking in this plane or in a direction of the plane and/or a rotation in the plane, in particular with the aid of the position-correcting device.

In one embodiment, the positional feature is constructed such that a position of the object in at least one direction, in particular in at least one plane, can be specified or determined with the aid of the positional feature.

As a result, in one embodiment, a position of the object, in particular in a plane, further in particular in a plane in which the position-correcting device is configured to correct the position of the object, can advantageously be determined on the basis of the, in particular individual, positional feature, in particular when the object has predetermined dimensions or is a semi-finished product with predetermined tolerances, in particular dimensions within the predetermined tolerances.

In one embodiment, the referencing device and/or the object carrier device has placeholders and/or recesses which are configured to receive a backlighting device, in particular at least a part of the backlighting device.

This advantageously makes it possible for the system to be used not only for one type of object, but also to be adapted to different types of objects, in particular semi-finished products, and further in particular to different positions (positions and/or orientations) of positional features of the objects.

In one embodiment, the backlighting device, in particular at least a part of the backlighting device, is arranged recessed with respect to the object carrier device, in particular with respect to a surface of the object carrier device on which the object is or will be arranged, in a direction away from the object, in particular in the z-direction.

As a result, in one embodiment, the at least one reference marking can advantageously be arranged at the same height, in particular at least substantially at the same distance from the surface of the object carrier device, as the positional feature of the object, in particular an edge of the object. Furthermore, in one embodiment, an actual position and/or a desired position can advantageously be determined (more) easily, in particular without having to include a height-based difference between the at least one reference marking and the positional feature, in particular the edge of the object, in the determination of the actual position and/or the desired position or without having to take the height-based difference into account during the determination.

In one embodiment, the height of the reference marking is configured such that it corresponds, at least substantially, to a height of the positional feature of the object. The term “height”, as used herein, should be understood in particular as the distance of the at least one reference marking from the surface of the object carrier device on which the object is or will be arranged and/or as the distance of the positional feature, in particular the (relevant) edge, of the object from this surface of the object carrier device, in the direction of the normal on this surface, in particular in the z-direction.

In one embodiment, the capturing device comprises a light filter, in particular a light filter for a predetermined wavelength or a predetermined light spectrum, in particular constructed for fluorescence.

In one embodiment, this advantageously allows a contrast of the capturing of the capturing device to be (further) improved, in particular a high or higher contrast to be achieved. In one embodiment, this is advantageous for the accuracy of determining the actual position and/or the desired position; in particular, in one embodiment, a (more) precise determination or position correction can be achieved or carried out.

In one embodiment, without limiting the generality, the object is a gas diffusion electrode or a gas diffusion layer, in particular of a fuel cell, which is to be or is aligned or its position is to be or is determined and/or corrected, in particular for a further production step, in particular for creating or manufacturing a fuel cell. In one embodiment, in particular due to production, a dimension in the x- or y-direction of the object is known, in particular due to production, within a predetermined tolerance, so that (advantageously) in this direction (only) the position of a positional feature of the object, in particular only the position of an edge of the object, has to be determined.

According to one embodiment, a method for determining the position and/or correcting the position of an object is provided, in particular with the aid of a system for determining and/or correcting the position described herein. In one embodiment, the method comprises backlighting at least a part of the object and/or backlighting at least one reference marking, in particular by means of a backlighting device, in particular a backlighting device described herein. In one embodiment, the method comprises capturing an image, in particular with the aid of a capturing device described herein, which comprises the at least one backlit part of the object and the at least one backlit reference marking. In one embodiment, the method comprises determining an actual position of the object based on the captured image, in particular based on determining a distance and/or a determined distance of the at least one positional feature of the object to the at least one reference marking. In one embodiment, the method comprises correcting the determined actual position of the object, in particular with the aid of a position-correcting device described herein, based on a predetermined desired position.

In one embodiment, the method comprises a step, in particular a preceding step, in which the object, the position of which is to be determined and/or corrected, is first transferred, in particular placed, onto the object carrier device, in particular by a robot or a machine, in particular a multi-axis machine, configured for this purpose.

In one embodiment, the system described herein and/or its means, in particular the reference marking, the object carrier device, the backlighting device, the capturing device and/or the position-correcting device, are configured to carry out a method described herein. In one embodiment, the method is carried out using a system described herein.

It is within the scope of the invention that the method steps described above are carried out in a different order and/or method steps are combined and/or one method step is integrated into another method step.

The term “position”, as used herein, is to be understood in particular as a position and/or an orientation, in particular with respect to the reference marking, further in particular as a pose, in particular with respect to a coordinate system, such as in particular the xyz coordinate system described herein.

The term “integrally joined”, as used herein, is to be understood in particular as mechanically operatively joined, in particular by form-fit, force-fit and/or material bonding.

The term “backlighting”, as used herein, is to be understood in particular to mean not “illuminating.” The term “backlighting”, as used herein, is to be understood in particular as backlighting of the reference marking and/or the object with respect to, in particular at least, one capturing device, in particular its perspective.

As possibly used herein, the terms, “comprises”, “contains”, “includes”, “encompasses”, “has”, “with,”, or any other variant thereof are intended to cover non-exclusive inclusion. For example, a method or a device that encompasses or comprises a list of elements is not necessarily restricted to these elements, but may include other elements that are not expressly listed or that are inherent to such a method or such a device.

Furthermore, unless expressly stated to the contrary, “or” refers to an inclusive or and not to an exclusive “or.” For example, a condition A or B is met by one of the following conditions: A is true (or present) and B is false (or absent), A is false (or absent) and B is true (or present), and both A and B are true (or present).

The terms “a” or “an,” as used herein, are defined in the meaning of “one or more.” The terms “another” and “a further” and any other variant thereof are to be understood to mean “at least one other.”

The term “plurality”, as possibly used herein, is to be understood to mean “two or more.”

The term “configured” or “arranged” to perform a specific function (and respective modifications thereof), possibly used herein, is to be understood to mean that the corresponding device or component thereof is already provided in a construction or adjustment in which it can execute the function or that it is at least adjustable—namely configurable—so that it can execute the function after corresponding adjustment. The configuration can take place, for example, via a corresponding adjustment of parameters of a process course or of switches or the like for activating or deactivating functionalities or settings. In particular, the device can have multiple predetermined configurations or operating modes, so that the configuration can be carried out by selecting one of these configurations or operating modes.

A system and/or a device encompassed by the system within the meaning of the present invention in particular at least in part can be constructed in terms of hardware and/or software, and can comprise in particular at least one in particular digital processing unit, in particular a microprocessor unit (CPU), graphics card (GPU) or the like, preferably data- or signal-connected to a storage and/or bus system, and/or one or more programs or program modules. The processing unit may be constructed to execute instructions implemented as a program stored in a storage system, to detect input signals from a data bus, and/or to provide output signals to a data bus. A storage system may comprise one or more, in particular different, storage media, in particular optical, magnetic, solid-status and/or other non-volatile media. The program can be constituted in such a way that it embodies or is capable of carrying out the methods described here, so that the processing unit can carry out the steps of such methods and thus in particular can operate or monitor the system for determining and/or correcting the position.

In one embodiment, a computer program or computer program product is provided, wherein the computer program or computer program product contains instructions, in particular stored on a computer-readable and/or non-volatile storage medium, which instructions, when executed by one or more computers or by a system described herein cause the computer(s) or the system to perform a method described herein.

In one embodiment, a computer program product can comprise a storage medium, in particular a computer-readable and/or non-volatile storage medium, for storing a program or instructions or with a program or instructions stored on the storage medium. In one embodiment, executing this program or these instructions by a system or a controller, in particular a computer or an arrangement of several computers, causes the system or the controller, in particular the computer(s), to carry out a method described here or one or more of its steps, or the program or the instructions are configured to do so.

In one embodiment, one or more, in particular all, steps of the method are performed completely or partially automatically, in particular by the controller or its means.

The computer program can in particular be stored on a non-volatile data carrier. Preferably the data carrier is in the form of an optical data carrier or a flash storage module. This can be advantageous if the computer program as such is to be handled independently of a processor platform on which the one or more programs are to be executed. In another implementation, the computer program can be present as a file on a data processing unit, in particular on a server, and can be downloaded via a data connection, for example the Internet or a dedicated data connection, such as a proprietary or local network. In addition, the computer program can have a plurality of interacting individual program modules. In particular, the modules can be configured or at least used in such a way that they are executed in the sense of distributed computing on different devices (such as computers or processor units) that are geographically remote from one another and connected to one another by a data network.

The system can accordingly have a program memory in which the computer program is stored. Alternatively, the system can also be configured to access a computer program available externally, for example on one or more servers or other data processing units, via a communication connection, in particular in order to exchange data with the computer program, which data are used during the execution of the method or computer program or represent outputs of the computer program.

Preferred embodiments of the device are described hereinafter, which in each case, unless expressly excluded or technically impossible, can be combined as desired with one another and with the further described other embodiments of the present solution. The features and advantages explained with respect to embodiments of the invention also apply correspondingly to the further embodiments of the invention.

Further advantages, features, and possible applications of the present invention result from the following detailed description in conjunction with the figures. In particular

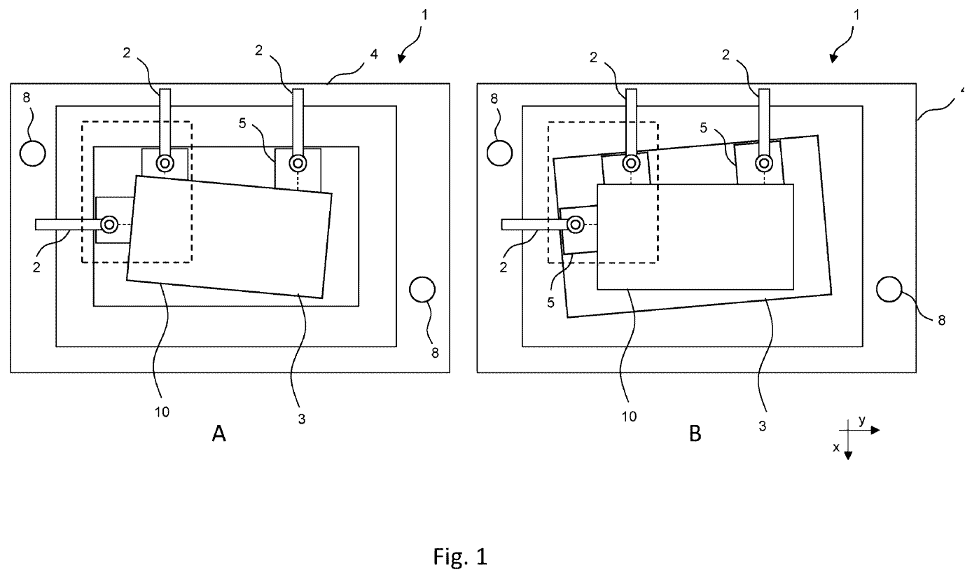

FIG. 1 schematically shows a position-determining and/or position-correcting system according to an embodiment in two different states;

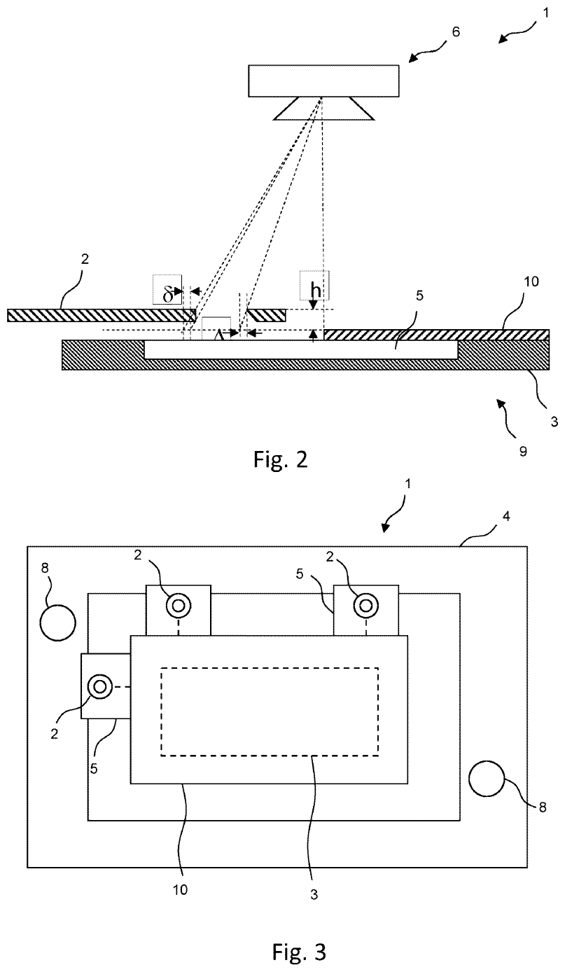

FIG. 2 schematically shows a sectional view of the system of FIG. 1;

FIG. 3 schematically shows a position-determining and/or position-correcting system according to an embodiment in a top view;

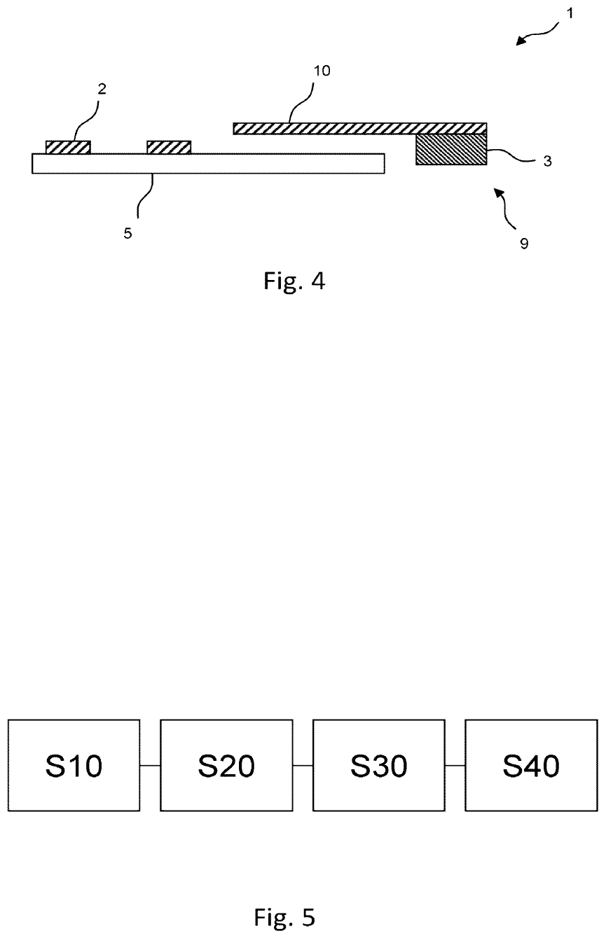

FIG. 4 schematically shows a sectional view of the system illustrated in FIG. 2; and

FIG. 5 shows a flowchart to illustrate a preferred embodiment of the method according to the invention.

In the figures, the same reference numerals denote the same, similar or corresponding elements. Elements illustrated in the figures are not necessarily illustrated to scale. Rather, the various elements illustrated in the figures are presented in such a way that their function and general purpose can be understood by the person skilled in the art. Connections and couplings, illustrated in the figures, between functional units and elements can also be implemented as an indirect connection or coupling, unless expressly stated otherwise. Functional units can be implemented in particular as hardware, software or a combination of hardware and software.

FIG. 1 schematically shows a position-determining and/or position-correcting system 1 in two different states, wherein in the state illustrated at A an object 10, the position of which is to be determined and/or corrected, in particular with respect to the desired position derivable from the schematically illustrated reference markings 2, is arranged on an object carrier device 3 or received there. The reference markings 2 are arranged on a referencing device 4. The reference markings 2 are illustrated as webs with a circular end and are arranged at a distance (here in particular from the plane of the paper) from the backlighting device 5, which is schematically illustrated as several rectangular backlighting surfaces. Furthermore, a field of view 7 (illustrated in dashed lines) of a capturing device 6 is shown. In the illustrated embodiment, this field of vision detects two reference markings 2, as well as two different edges of the rectangular object 10, which are used as positional features of the object 10. The backlighting device 5 is integrated into the object carrier device 3 and can move with it, in particular in one plane. The referencing device 4 is further shown with receptacles 8, which in turn can be used as a reference for a process machine or device, such as in particular a pick-and-place robot or in a carrier system, so that in particular a position of the object relative to the receptacles 8, or to the pick-and-place robot or to the carrier system, is known. In FIG. 1 A, a distance of the reference markings 2 to the edges of the object 10 is also illustrated in dashed lines. From these distances, in particular by means of a method described herein, an actual position of the object 10 relative to the reference markings 2 can be determined and, accordingly, a position correction of the object 10 can be carried out using a position-correcting device 9, so that the object assumes a predetermined desired position. Furthermore, FIG. 1 shows an example of a coordinate system with x- and y-directions. In the exemplary illustration, object 10 is rotated and translated in the xy-plane.

This is particularly illustrated as an example in FIG. 1 B. The object 10 is corrected into a desired position by means of the position-correcting device 9, which is not illustrated but is configured to manipulate the object carrier device 3 in such a way that the object 10 received in the object carrier device 3 can be position-corrected. For the illustrated embodiment, the desired position results from a predetermined distance of the object edges to the reference markings 2. This distance can be or is checked or verified with the capturing device. As can be seen in FIG. 1 B, it is illustrated by way of example that the object carrier device 3 was rotated in the plane of the page with respect to FIG. 1 A in order to transfer the object 10 from the actual position in FIG. 1 A to the desired position in FIG. 1 B. This results in a known coordinate transformation from the images of the referencing device 4 to the object 10, the position of which is thus known. In one embodiment, the perspective of the capturing device has at least two reference markings. In one embodiment, the position of the capturing device 6 relative to the reference markings 2 can thereby advantageously be determined, in particular relative to the desired position of the object 10.

FIG. 2 schematically shows a sectional view of the system of FIG. 1. The reference marking 2 is arranged at a distance from the backlighting device 5, in particular such that the object carrier device 3 or the position-correcting device 9 can move without colliding with the reference marking 2 or being hindered in its movement by it. The object 10 is arranged on the object carrier device 3 or is received by it. Furthermore, the object 10 is received in such a way that at least a part of the object 10 is or can be backlit by the backlighting device 5. Furthermore, a capturing device 6 is shown which has a perspective or a field of view that detects both the reference marking 2 and the edge of the object 10. In one embodiment, the contour of the reference marking 2 is chamfered in order to minimize or prevent an offset δ (illustrated in particular as an example on the right side of the reference marking 2). Furthermore, in one embodiment, the reference marking 2 is arranged with an offset h with respect to an upper edge of the object 10 in the z-direction, wherein in one embodiment the position-correcting device 9 is configured to correct the object in an xy-plane in its position (in the x-direction and y-direction, as well as at an angle in the xy-plane), so that in particular an offset in the detection of the position(s) Δ is or can be reduced. In one embodiment, the reference marking 2 is arranged at the same height (in the z-direction) as a positional feature of the object 10, in particular at the same height as an (upper) edge of the object (10). In one embodiment, the height of the reference marking 2 (in the z-direction) can be adjusted such that an (upper) edge of the object 10 and the height of the reference marking 2 coincide, at least substantially.

FIG. 3 schematically shows a position-determining and/or position-correcting system 1 according to an embodiment in a top view. In the exemplary illustration, the backlighting device 5 is arranged on the referencing device 4 or joined to the referencing device. Furthermore, the reference markings 2 are arranged on the backlighting device 5, in particular directly on a surface of the backlighting device 5. The object carrier device 3 is illustrated smaller than the object 10 and is also used as a position-correcting device 9. If an actual position of the object 10 does not correspond to a predetermined desired position, the object 10 is transferred from the actual position to the desired position with the aid of the position-correcting device 9, in particular based on the actual position determined with the aid of the backlit reference marking(s) 2 and the backlit positional features of the object 10, in particular the edge(s) of the object 10. The referencing device 4 has receptacles 8 with which the desired position for a gripper and/or a carrier system can be referenced.

FIG. 4 schematically shows a sectional view of the system 1 illustrated in FIG. 2. The backlighting device 5 is arranged such that a positional feature of the object 10, here the edge of the object 10, can be or is backlit. Furthermore, the reference marking 2 is arranged on the backlighting device 5. The object 10 is arranged on the object carrier device 3, which in the exemplary representation of the system 1 is not operatively joined to the backlighting device 5. In one embodiment, the reference marking 2 comprises a chamfer (not illustrated).

FIG. 5 schematically shows a flowchart to illustrate an embodiment of the method according to the invention. The method comprises backlighting S10 of at least one part of the object 10 and backlighting of at least one reference marking 2, in particular with the aid of the backlighting device 5. The method further comprises capturing S20 an image, in particular with the aid of a capturing device 6 which comprises the at least one backlit part of the object 10 and the at least one backlit reference marking 2. The method further comprises determining S30 an actual position of the object 10 based on the captured image. FIG. 5 further comprises correcting S40 the determined actual position of the object 10, optionally according to an embodiment, in particular with the aid of a position-correcting device described herein, based on a predetermined desired position.

While at least one exemplary embodiment has been described above, it is to be noted that a large number of variations of variations exist. It is also to be noted that the exemplary embodiments described only represent non-limiting examples, and are not intended to restrict the scope, the applicability, or the configuration of the devices and methods described herein. Rather, the preceding description will provide those skilled in the art with guidance for implementing at least one exemplary embodiment, wherein it is understood that various changes in the operation and arrangement of elements described in an exemplary embodiment may be made without departing from the scope of the subject matter defined in the appended claims and their legal equivalents.

### LIST OF REFERENCE NUMERALS

1 Position-determining and/or position-correcting system
2 Reference marking
3 Object carrier device
4 Referencing device
5 Backlighting device
6 Capturing device
7 Field of view of the capturing device
8 Receptacle
9 Position-correcting device
10 Object
S10 Backlighting
S20 Capturing an image
S30 Determining an actual position
S40 Correcting the object position

What is claimed is:

1. A system for determining and/or correcting the position of an object, comprising:
at least one reference marking which is constructed to indicate a desired position of an object;
an object carrier device for receiving the object;
a backlighting device for backlighting the at least one reference marking and for backlighting at least one part of the object;
at least one capturing device for capturing an image, wherein the capturing device is configured to detect an actual position of the object, in particular based on the at least one positional feature of the object, and the desired position of the object, in particular based on the at least one reference marking; and
at least one position-correcting device which is constructed to correct the position of the received object based on the detected actual position and the detected desired position of the object, wherein the object carrier device and the at least one position-correcting device are integrally joined to one another.

2. (canceled)

3. The system according to claim 1, wherein the backlighting device is arranged on a referencing device and/or on the object carrier device.

4. The system according to claim 1, wherein the reference marking is arranged at a distance from the backlighting device, in particular if the backlighting device is arranged on the object carrier device, or in that the reference markings are arranged on the backlighting device, in particular if the backlighting device is arranged on the referencing device.

5. The system according to claim 1, wherein the object carrier device and/or the backlighting device is/are configured to provide a negative pressure, in particular to fix the object.

6. The system according to claim 1, wherein a light emitted by the backlighting device has a wavelength which lies in the visible wavelength range and/or in the non-visible wavelength range, in particular in the ultraviolet range or in the infrared range.

7. The system according to claim 1, wherein the backlighting device has a plurality of, in particular mutually independent, backlighting elements which are configured to backlight at least one and/or at most one reference marking.

8. The system according to claim 1, wherein the capturing device comprises a plurality of cameras, in particular one camera for each reference marking, for each of at least two of the reference markings and/or for each positional feature of the object.

9. The system according to claim 8, wherein the capturing device has reference markings for determining a pose of the plurality of cameras.

10. The system according to claim 1, wherein the position-correcting device is configured to correct a position of the object in a spatial plane.

11. The system according to claim 1, wherein the reference markings are ring-shaped and/or have a chamfer.

12. The system according to claim 1, wherein the referencing device is constructed for a carrier system process or a pick-and-place process.

13. The system for determining and/or correcting the position of an object, wherein the system comprises:
backlighting at least one part of the object and backlighting at least one reference marking, in particular with the aid of the backlighting device;
capturing an image, in particular with the aid of the capturing device which comprises the at least one backlit part of the object and the at least one backlit reference marking;
determining an actual position of the object based on the captured image.

14. The method according to claim 13, wherein the object, the position of which is to be detected and/or corrected is first transferred, in particular placed, onto the object carrier device.

15. The method according to claim 13, wherein the method comprises:
correcting the determined actual position of the object, in particular with the aid of a position-correcting device described herein, based on a predetermined desired position.

16. The system according to claim 3, wherein the reference marking is arranged at a distance from the backlighting device, in particular if the backlighting device is arranged on the object carrier device, or in that the reference markings are arranged on the backlighting device, in particular if the backlighting device is arranged on the referencing device.

17. The system according to claim 3, wherein the object carrier device and/or the backlighting device is/are configured to provide a negative pressure, in particular to fix the object.

18. The system according to claim 3, wherein a light emitted by the backlighting device has a wavelength which lies in the visible wavelength range and/or in the non-visible wavelength range, in particular in the ultraviolet range or in the infrared range.

19. The system according to claim 3, wherein the backlighting device has a plurality of, in particular mutually independent, backlighting elements which are configured to backlight at least one and/or at most one reference marking.

20. The system according to claim 3, wherein the capturing device comprises a plurality of cameras, in particular one camera for each reference marking, for each of at least two of the reference markings and/or for each positional feature of the object.

21. The method according to claim 14, wherein the method comprises:
correcting the determined actual position of the object, in particular with the aid of a position-correcting device described herein, based on a predetermined desired position.
